(19) United States
(12) Patent Application Publication
(10) Pub. No.: US 2024/0194596 A1
(43) Pub. Date: Jun. 13, 2024

(54) SEMICONDUCTOR DEVICE

(71) Applicant: Kioxia Corporation, Tokyo (JP)

(72) Inventor: Hanae ISHIHARA, Yokkaichi (JP)

(73) Assignee: Kioxia Corporation, Tokyo (JP)

(21) Appl. No.: 18/458,196

(22) Filed: Aug. 30, 2023

(30) Foreign Application Priority Data
Dec. 9, 2022 (JP) 2022-197296

(51) Int. Cl. H01L 23/528; G11C 16/04; H10B 41/27; H10B 43/27

(52) U.S. Cl. CPC H01L 23/5283; G11C 16/0483; H10B 41/27; H10B 43/27

(57) ABSTRACT

In one embodiment, a semiconductor device includes a substrate, a first stacked film provided above the substrate, includes a plurality of electrode layers and a plurality of first insulators that are alternately stacked in a first direction, and included in a memory cell array, and a second stacked film provided above the substrate, includes one or more first insulators of the plurality of first insulators, and one or more first films that are stacked alternately with the one or more first insulators in the first direction. The device further includes a first plug provided in the second stacked film, and a first interconnect layer provided on the memory cell array and the first plug, and electrically connected to the memory cell array and the first plug.

### CROSS-REFERENCE TO RELATED APPLICATIONS

This application is based upon and claims the benefit of priority from the prior Japanese Patent Application No. 2022-197296, filed on Dec. 9, 2022, the entire contents of which are incorporated herein by reference.

### FIELD

Embodiments described herein relate to a semiconductor device.

### BACKGROUND

In some cases, a three-dimensional semiconductor memory is manufactured by forming an opening on a memory cell array, forming another opening on a via plug, and burying the same interconnect layer in these openings. In these cases, when the openings are simultaneously formed, over etching may occur in the opening on the via plug, which may cause abnormality in the interconnect layer on the via plug. Meanwhile, when the openings are sequentially formed, this increases the number of processes for etching.

### BRIEF DESCRIPTION OF THE DRAWINGS

FIG. 1 is a cross-sectional view showing a structure of a semiconductor device of a first embodiment;

FIG. 2 is an enlarged cross-sectional view showing the structure of the semiconductor device of the first embodiment;

FIGS. 3 and 4 are cross-sectional views showing a method of manufacturing the semiconductor device of the first embodiment;

FIG. 5 is a cross-sectional view showing the structure of the semiconductor device of the first embodiment;

FIGS. 6A to 7B are cross-sectional views showing a method of manufacturing a semiconductor device of a first comparative example of the first embodiment;

FIGS. 8A to 9B are cross-sectional views showing a method of manufacturing a semiconductor device of a second comparative example of the first embodiment;

FIGS. 10A to 11B are cross-sectional views showing the method of manufacturing the semiconductor device of the first embodiment;

FIGS. 12A to 16B are cross-sectional views showing the method of manufacturing the semiconductor device of the first embodiment;

FIG. 17 is a cross-sectional view showing the structure of a semiconductor device of a first modification of the first embodiment;

FIG. 18 is a cross-sectional view showing the structure of a semiconductor device of a second modification of the first embodiment;

FIG. 19 is a cross-sectional view showing the structure of a semiconductor device of a third modification of the first embodiment before dicing;

FIGS. 20A and 20B are cross-sectional views showing a method of manufacturing a semiconductor device of a fourth modification of the first embodiment;

FIGS. 21A and 21B are cross-sectional views showing a method of manufacturing a semiconductor device of a fifth modification of the first embodiment;

FIGS. 22A and 22B are cross-sectional views showing the structure of a semiconductor device of a second embodiment;

FIGS. 23A to 24B are cross-sectional views showing a method of manufacturing the semiconductor device of the second embodiment;

FIG. 25 is a cross-sectional view showing the structure of a semiconductor device of a third embodiment;

FIGS. 26A and 26B are cross-sectional views showing a method of manufacturing the semiconductor device of the third embodiment;

FIG. 27 is a cross-sectional view showing the structure of a semiconductor device of a fourth embodiment;

FIGS. 28A to 32B are cross-sectional views showing a method of manufacturing the semiconductor device of the fourth embodiment; and

FIG. 33 is a cross-sectional view showing the structure of the semiconductor device of the fourth embodiment before bonding.

### DETAILED DESCRIPTION

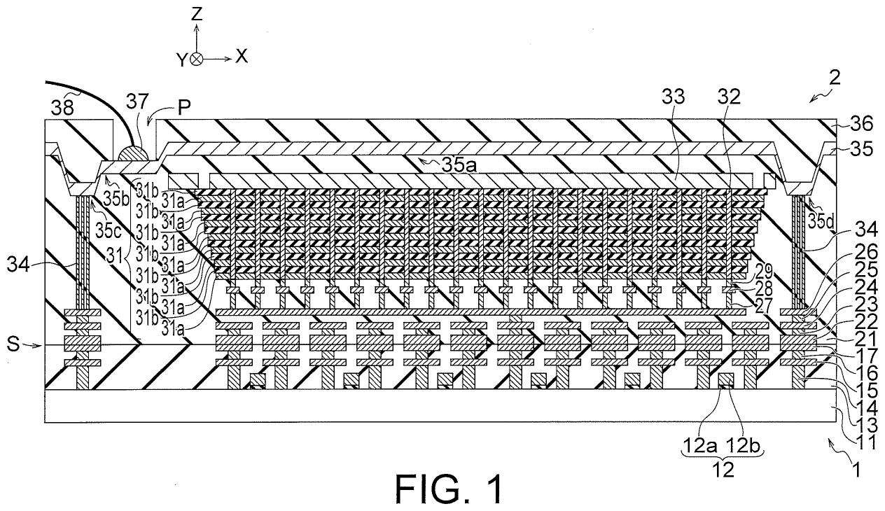

Embodiments will now be explained with reference to the accompanying drawings. The same components in FIGS. 1 to 33 are assigned the same reference signs and redundant descriptions will be omitted.

In one embodiment, a semiconductor device includes a substrate, a first stacked film provided above the substrate, includes a plurality of electrode layers and a plurality of first insulators that are alternately stacked in a first direction, and included in a memory cell array, and a second stacked film provided above the substrate, includes one or more first insulators of the plurality of first insulators, and one or more first films that are stacked alternately with the one or more first insulators in the first direction. The device further includes a first plug provided in the second stacked film, and a first interconnect layer provided on the memory cell array and the first plug, and electrically connected to the memory cell array and the first plug.

### First Embodiment

FIG. 1 is a cross-sectional view showing the structure of a semiconductor device of a first embodiment.

The semiconductor device of the present embodiment is, for example, a three-dimensional semiconductor memory of a circuit chip 1 and an array chip 2 bonded together. Reference sign S shown in FIG. 1 indicates a bonding face between the circuit chip 1 and the array chip 2.

As shown in FIG. 1, the circuit chip 1 includes a substrate 11, a plurality of transistors 12, an inter layer dielectric 13, a plurality of contact plugs 14, an interconnect layer 15, a plurality of via plugs 16, and a plurality of metal pads 17. The transistors 12 each include a gate insulator 12a and a gate electrode 12b.

As shown in FIG. 1, the array chip 2 includes an inter layer dielectric 21, a plurality of metal pads 22, a plurality of via plugs 23, an interconnect layer 24, a plurality of via plugs 25, an interconnect layer 26, a plurality of via plugs 27, an interconnect layer 28, a plurality of contact plugs 29, a stacked film 31, a plurality of columnar portions 32, an interconnect layer 33, a plurality of via plugs 34, an interconnect layer 35, a passivation insulator 36, solder 37, and a bonding wire 38. The stacked film 31 includes a plurality of electrode layers 31a and a plurality of insulators 31b. The interconnect layer 35 includes a flat portion 35a, a contact portion 35b, a contact portion 35c, and a contact portion 35d. The stacked film 31 is an example of the first stacked film, the insulator 31b is an example of a first insulator, the interconnect layer 33 is an example of a second interconnect layer, the via plugs 34 are an example of the first plug, and the interconnect layer 35 is an example of the first interconnect layer. In FIG. 1, illustration of a stacked film 31′ described later is omitted.

The substrate 11 is, for example, a semiconductor substrate, such as a Si (silicon) substrate. FIG. 1 shows an X-direction and a Y-direction that are parallel to the surface of the substrate 11 and are perpendicular to each other, and a Z-direction perpendicular to the surface of the substrate 11. The X-direction, the Y-direction, and the Z-direction cross one another. In the present specification, a +Z-direction is assumed to be an upward direction and a −Z-direction is assumed to be a downward direction. The −Z-direction may or may not correspond to the gravity direction. The Z-direction is an example of a first direction.

The transistors 12 each include the gate insulator 12a and the gate electrode 12b that are provided in order on the substrate 11 and a source diffusion layer and a drain diffusion layer (not shown) that are provided in the substrate 11. The transistors 12 form, for example, a logic circuit (CMOS circuit) that controls the operation of a memory cell array in the array chip 2.

The inter layer dielectric 13 is formed on the substrate 11 and covers the transistors 12. The inter layer dielectric 13 is, for example, a stacked film including a SiO₂ film (silicon oxide film) and other insulators.

The contact plugs 14, the interconnect layer 15, the via plugs 16, and the metal pads 17 are formed in the inter layer dielectric 13 and are disposed in order on the substrate 11 (or on the transistors 12). As shown in FIG. 1, the interconnect layer 15 includes a plurality of interconnects. The metal pads 17 are, for example, a metal layer including a Cu (copper) layer.

The inter layer dielectric 21 is formed on the inter layer dielectric 13. The inter layer dielectric 21 is, for example, a stacked film including a SiO₂ film and other insulators.

The metal pads 22, the via plugs 23, the interconnect layer 24, the via plugs 25, and the interconnect layer 26 are formed in the inter layer dielectric 21 and are disposed in order on the metal pads 17. The metal pads 22 contact and are electrically connected to the corresponding metal pads 17. The metal pads 22 are, for example, a metal layer including a Cu layer. As shown in FIG. 1, the interconnect layers 24, 26 include a plurality of interconnects.

The via plugs 27, the interconnect layer 28, and the contact plugs 29 are formed in the inter layer dielectric 21 and are disposed in order on the interconnect layer 26. As shown in FIG. 1, the interconnect layer 28 includes a plurality of interconnects. These interconnects include a plurality of bit lines.

The stacked film 31, the columnar portions 32, and the interconnect layer 33 are formed in the inter layer dielectric 21 and form the aforementioned memory cell array. The memory cell array includes a plurality of memory cells (cell transistors) and data can be stored in these memory cells. The operation of the memory cell array is controlled by the aforementioned logic circuit via the metal pads 17, 22 and the like.

The stacked film 31 includes the plurality of electrode layers 31a and the plurality of insulators 31b that are alternately stacked in the Z-direction. The electrode layers 31a are, for example, a metal layer including a W (tungsten) layer and function as a word line or a select line. The insulators 31b are, for example, a SiO₂ film.

The columnar portions 32 are formed on the contact plugs 29 in the stacked film 31 and have a columnar shape extending in the Z-direction. Lower ends of the columnar portions 32 are electrically connected to the aforementioned bit lines and upper ends of the columnar portions 32 are electrically connected to a source line described later. Further details of the columnar portions 32 will be described later.

The interconnect layer 33 is formed on the stacked film 31. As shown in FIG. 1, the interconnect layer 33 includes a plurality of interconnects. Of these interconnects, the interconnects disposed on the columnar portions 32 function as the source line.

The via plugs 34 are formed in the inter layer dielectric 21 and are disposed on the interconnect layer 26. The interconnect layer 35 is formed on the inter layer dielectric 21 and the via plugs 34. The interconnect layer 35 includes one or more interconnects. The interconnect layer 35 is, for example, a metal layer including an Al (aluminum) layer. The passivation insulator 36 is formed on the inter layer dielectric 21 via the interconnect layer 35. FIG. 1 shows an opening P provided in the passivation insulator 36.

The interconnect layer 35 includes the flat portion 35a, the contact portion 35b, the contact portion 35c, and the contact portion 35d. The interconnect layer 35 further includes inclined portions that connect the flat portion 35a, the contact portion 35b, the contact portion 35c, and the contact portion 35d.

The flat portion 35a is generally positioned above the stacked film 31, the columnar portions 32, and the interconnect layer 33, and has flat upper and lower faces. The flat portion 35a of the present embodiment occupies most of the area of the interconnect layer 35 in a plan view.

The contact portion 35b is provided at a lower position than the flat portion 35a, for use in wire bonding. In FIG. 1, an upper face of the contact portion 35b is exposed in the opening P and the bonding wire 38 is electrically connected to the upper face of the contact portion 35b in the opening P by means of the solder 37. The bonding wire 38 is used for, for example, electrically connecting the semiconductor device of the present embodiment and other devices.

The contact portion 35c is provided at a lower position than the contact portion 35b, for use in plug connection. In FIG. 1, the contact portion 35c is disposed on the plurality of via plugs 34 and is electrically connected to these via plugs 34.

The contact portion 35d is provided at a lower position than the flat portion 35a, for use in plug connection. In FIG. 1, the contact portion 35d is disposed on the plurality of via plugs 34 and is electrically connected to these via plugs 34.

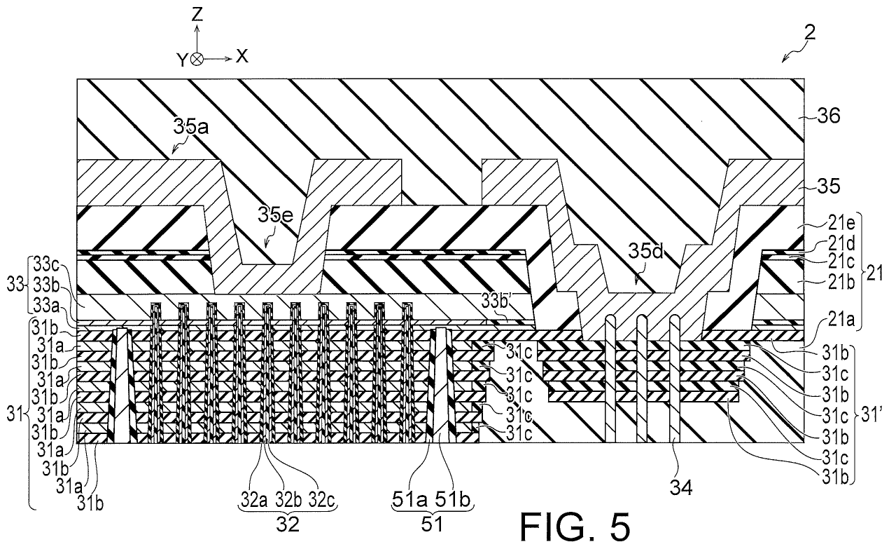

The interconnect layer 35 may further include a contact portion electrically connected to the source line (interconnect layer 33). Such a contact portion will be described later with reference to FIG. 5.

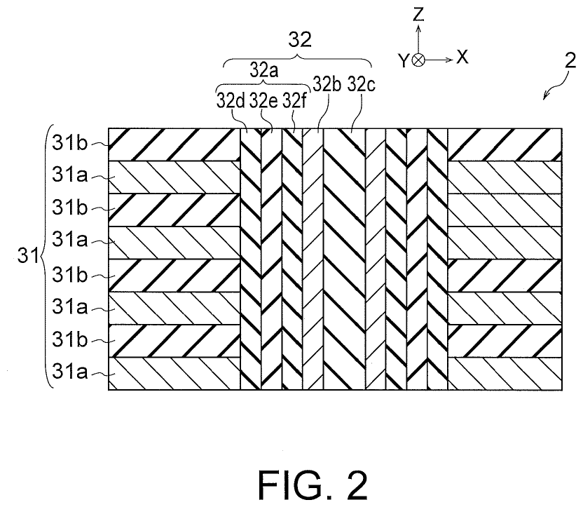

FIG. 2 is an enlarged cross-sectional view showing the structure of the semiconductor device of the first embodiment. FIG. 2 illustrates one of the aforementioned plurality of columnar portions 32.

As shown in FIG. 2, the columnar portions 32 each include a memory insulator 32a, a channel semiconductor layer 32b, and a core insulator 32c that are provided in order in the stacked film 31. The memory insulator 32a includes a block insulator 32d, a charge accumulation layer 32e, and a tunnel insulator 32f that are provided in order in the stacked film 31. The channel semiconductor layer 32b is an example of the semiconductor layer.

The block insulator 32d, the charge accumulation layer 32e, the tunnel insulator 32f, and the channel semiconductor layer 32b have a tubular shape extending in the Z-direction and the core insulator 32c has a columnar shape extending in the Z-direction. The block insulator 32d is, for example, a SiO₂ film. The charge accumulation layer 32e is, for example, an insulator, such as a SiN film (silicon nitride film) or a semiconductor layer, such as a polysilicon layer. The charge accumulation layer 32e can accumulate signal charges of the memory cells. The tunnel insulator 32f is, for example, a SiO₂ film. The channel semiconductor layer 32b is, for example, a polysilicon layer. The channel semiconductor layer 32b is electrically connected to the aforementioned bit line (interconnect layer 28) and source line (interconnect layer 33). The core insulator 32c is, for example, a SiO₂ film.

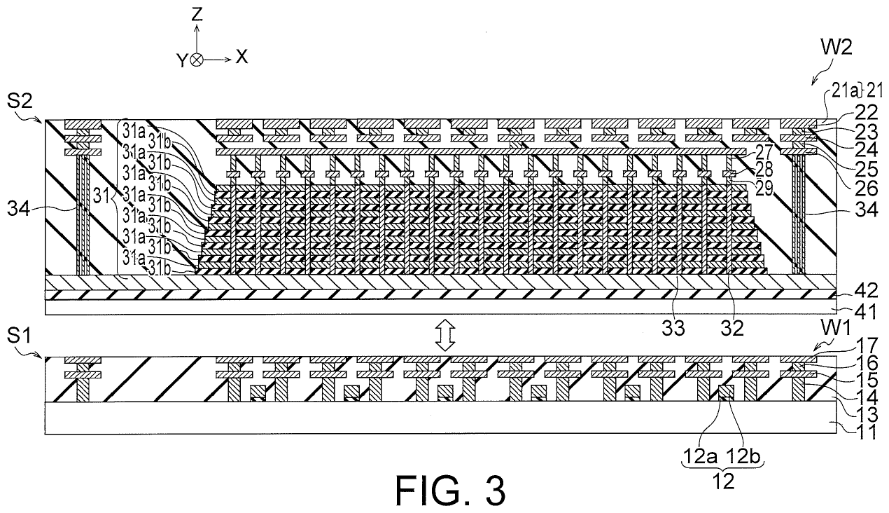

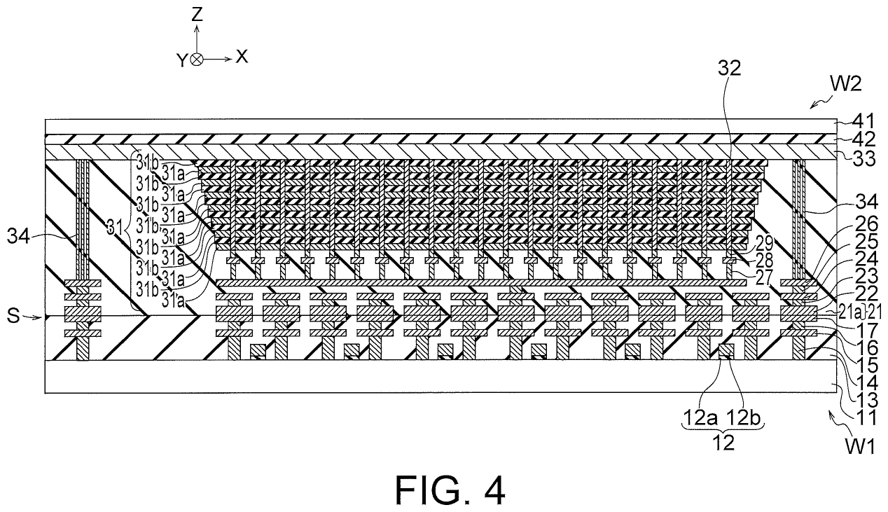

FIGS. 3 and 4 are cross-sectional views showing a method of manufacturing the semiconductor device of the first embodiment.

FIG. 3 shows a circuit wafer W1 including a plurality of circuit chips 1 and an array wafer W2 including a plurality of array chips 2. The orientation of the array wafer W2 shown in FIG. 3 is opposite to that of the array chip 2 shown in FIG. 1. In the present embodiment, the semiconductor device is manufactured by bonding the circuit wafer W1 and the array wafer W2 together. FIG. 3 shows the array wafer W2 before the orientation is reversed for bonding, and FIG. 1 shows the array chip 2 after being bonded in the reversed orientation for bonding and diced.

In FIG. 3, reference sign S1 shows an upper face of the circuit wafer W1 and reference sign S2 shows an upper face of the array wafer W2. The array wafer W2 includes a substrate 41 provided below the interconnect layer 33 via an insulator 42. The substrate 41 is, for example, a semiconductor substrate, such as a Si substrate.

In the present embodiment, as shown in FIG. 3, first, the transistors 12, the inter layer dielectric 13, the metal pads 17, and the like are formed on the substrate 11 of the circuit wafer W1 and the inter layer dielectric 21, the metal pads 22, the stacked film 31, the columnar portions 32, the interconnect layer 33, the via plugs 34, the insulator 42, and the like are formed on the substrate 41 of the array wafer W2. For the inter layer dielectric 21, an insulator 21a forming a part of the inter layer dielectric 21 is formed. Next, as shown in FIG. 4, the circuit wafer W1 and the array wafer W2 are bonded together with a mechanical pressure. In this manner, the inter layer dielectric 13 and the inter layer dielectric 21 are affixed together. Next, the circuit wafer W1 and the array wafer W2 are annealed. In this manner, the metal pads 17 and the metal pads 22 are joined together.

Thereafter, the substrate 11 is thinned by CMP (Chemical Mechanical Polishing), and the substrate 41 and the insulator 42 are removed by CMP. Further, the interconnect layer 33 is processed by etching to form the interconnect layer 35 and the passivation insulator 36 on the substrate 11. At this time, the remaining insulators that form the inter layer dielectric 21 are also formed. Further, the circuit wafer W1 and the array wafer W2 are cut into a plurality of chips and the bonding wire 38 is attached to the interconnect layer 35 by means of the solder 37. In this manner, the semiconductor device shown in FIG. 1 is manufactured.

Although FIG. 1 illustrates a boundary face between the inter layer dielectric 13 and the inter layer dielectric 21 and a boundary face between the metal pads 17 and the metal pads 22, these boundary faces are generally not observed after the aforementioned annealing. However, the positions where these boundary faces were present can be estimated by, for example, detecting the inclination of the side faces of the metal pads 17 or the side faces of the metal pads 22, or the positional deviation between the side faces of the metal pads 17 and the metal pads 22.

Further, in the present embodiment, the circuit chip 1 and the array chip 2 are bonded together, but the array chips 2 may be bonded together instead.

Furthermore, in the present embodiment, the substrate 41 is removed by CMP, but may be peeled off from the substrate 11 at a position of the insulator 42 to be removed. This makes it possible to reuse the substrate 41, for example.

FIG. 5 is a cross-sectional view showing the structure of the semiconductor device of the first embodiment. FIG. 5 shows a cross section of the aforementioned array chip 2.

In FIG. 5, the inter layer dielectric 21 includes the insulator 21a, an insulator 21b, an insulator 21c, an insulator 21d, and an insulator 21e. The insulator 21a is formed on the inter layer dielectric 13 (see FIG. 4). The insulators 21b to 21d are formed in order on the insulator 21a via the interconnect layer 33 or the like. The insulator 21e is formed on the insulator 21d and includes portions formed in the interconnect layer 33 and the insulators 21b to 21d.

In FIG. 5, the array chip 2 includes a plurality of slit portions 51. These slit portions 51 are formed in the stacked film 31 and have a plate-like shape extending in the Y-direction and the Z-direction. The slit portions 51 each include an insulator 51a and an interconnect layer 51b that are formed in order in the stacked film 31. The insulator 51a is, for example, a SiO₂ film. The interconnect layer 51b is electrically connected to the interconnect layer 33.

In FIG. 5, the array chip 2 further includes the stacked film 31′. The stacked film 31′ includes a plurality of insulators 31c and the plurality of insulators 31b that are alternately stacked in the Z-direction and is formed in the insulator 21a. The insulators 31c are formed of an insulating material that differs from that of the insulators 31b and are, for example, a SiN film. The stacked film 31′ is an example of the second stacked film. The insulators 31c are an example of a first film and also an example of a second insulator.

The stacked films 31, 31′ are formed such that the plurality of insulators 31c and the plurality of insulators 31b are alternately stacked in the Z-direction and these insulators 31c and insulators 31b are processed into the stacked films 31, 31′. Thereafter, these insulators 31c in the stacked film 31 are replaced with the plurality of electrode layers 31a by a replacement process. Accordingly, the insulators 31b in the stacked film 31′ are positioned at the same heights as that of the corresponding insulators 31b in the stacked film 31 and the insulators 31c in the stacked film 31′ are positioned at the same heights as that of the corresponding electrode layers 31a in the stacked film 31.

The insulators 31c are used as a sacrificial layer for replacement with the electrode layers 31a in the replacement process. In the replacement process, the insulators 31c between the insulators 31b are removed by wet etching and as a result, a plurality of cavities are formed between the insulators 31b and the plurality of electrode layers 31a is formed in these cavities. At this time, the wet etching of the present embodiment is performed so as to remove the insulators 31c in the stacked film 31 without removing the insulators 31c in the stacked film 31′. As a result, the stacked film 31 shown in FIG. 5 includes the plurality of electrode layers 31a and the plurality of insulators 31b and the stacked film 31′ shown in FIG. 5 includes the plurality of insulators 31c and the plurality of insulators 31b. However, the stacked film 31 shown in FIG. 5 also includes a small portion of the insulators 31c that were not removed by the wet etching. The stacked film 31 may not include such an insulator 31c. The wet etching is performed by supplying a liquid medicine for wet etching to the insulators 31c through slits for filling the slit portions 51.

In the present embodiment, when the plurality of insulators 31c and the plurality of insulators 31b are processed into the stacked films 31, 31′, the insulators 31c are divided into the insulators 31c in the stacked film 31 and the insulators 31c in the stacked film 31′. As a result, the insulators 31c in the stacked film 31′ do not contact the corresponding electrode layers 31a or insulators 31c in the stacked film 31. Further, except for the uppermost insulator 31b, the insulators 31b are divided into the insulators 31b in the stacked film 31 and the insulators 31b in the stacked film 31′. As a result, except for the uppermost insulator 31b, the insulators 31b in the stacked film 31′ do not contact the corresponding insulators 31b in the stacked film 31.

In FIG. 5, the interconnect layer 33 includes three layers 33a, 33b, 33c formed on the stacked film 31. FIG. 5 further shows an insulator 33b′. The interconnect layer 33 is formed such that before bonding described above, the layer 33c, the insulator 33b′, and the layer 33a are formed in order and the insulator 33b′ is partially replaced with the layer 33b. Accordingly, the insulator 33b′ is positioned between the layer 33a and the layer 33c and is positioned at the same height as that of the layer 33b. The layers 33a to 33c are, for example, a polysilicon layer.

In FIG. 5, the via plugs 34 are formed in the insulator 21a, the stacked film 31′, and the interconnect layer 35 and extend through the stacked film 31′ in the Z-direction. The via plugs 34 shown in FIG. 5 have upper ends at a higher position than an upper face of the stacked film 31′ (upper face of the uppermost insulator 31b).

In FIG. 5, the interconnect layer 35 includes the flat portion 35a, a contact portion 35e provided at a lower position than the flat portion 35a, and the contact portion 35d provided at a lower position than the contact portion 35e. The contact portion 35e is formed on the source line (interconnect layer 33) and is electrically connected to the source line. The contact portion 35d is formed on the stacked film 31′ and the plurality of via plugs 34 and are electrically connected to these via plugs 34.

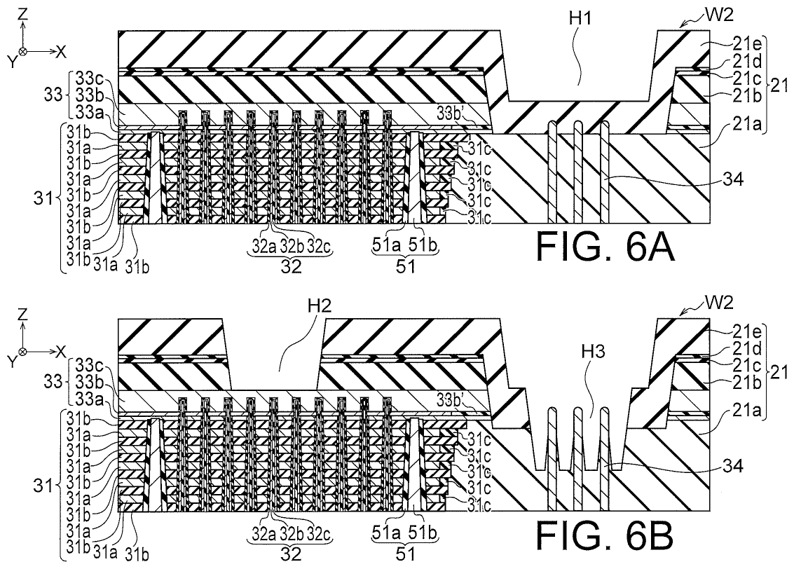

Next, with reference to FIGS. 6A to 11B, the first embodiment and first and second comparative examples of the first embodiment are compared.

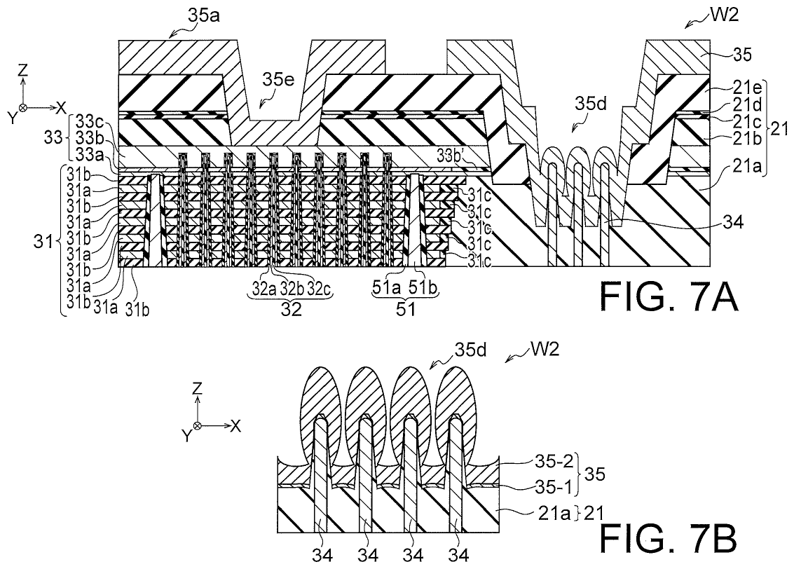

FIGS. 6A to 7B are cross-sectional views showing a method of manufacturing a semiconductor device of the first comparative example of the first embodiment.

FIG. 6A shows a process performed after the process shown in FIG. 4. In the present comparative example, the substrate 41 and the insulator 42 shown in FIG. 4 are removed and subsequently, the insulators 21b to 21d are formed in order on the layer 33c (FIG. 6A). Next, by lithography and RIE (Reactive Ion Etching), an opening H1 is formed in the insulators 21b to 21d, the layer 32c, the insulator 32b′, and the layer 32a, and the insulator 21a and the plurality of via plugs 34 are exposed in the opening H1 (FIG. 6A). Next, the insulator 21e is formed on the insulator 21d (FIG. 4A). As a result, the insulator 21e is formed on a bottom face and a side face of the opening H1 so that the aforementioned via plugs 34 are covered with the insulator 21e. The array wafer W2 of the present comparative example does not include the stacked film 31′ in the insulator 21a.

Next, openings H2, H3 are simultaneously formed in the insulator 21e by lithography and RIE (FIG. 6B). The opening H2 is formed so as to extend through the insulators 21b to 21e and reach the source line (interconnect layer 33). The opening H3 is formed in the opening H1 so as to extend through the insulator 21e. As a result, the via plugs 34 are exposed in the opening H3.

Here, the insulator 21e is a SiO₂ film and a portion near an upper face of the insulator 21a is also a SiO₂ film. In this case, the opening H3 extends through the insulator 21e and then reaches the upper face of the insulator 21a without passing an etch stopper. Accordingly, the opening H3 shown in FIG. 6B is formed not only in the insulator 21e, but also deeply in the insulator 21a. As a result, the length of the via plugs 34 exposed in the opening H3 becomes longer. Since the depth of the opening H2 generally corresponds to the thickness of the insulators 21b to 21e, the depth of the opening H3 formed simultaneously with the opening H2 also generally corresponds to the thickness of the insulators 21b to 21e.

Next, the interconnect layer 35 is formed on the inter layer dielectric 21 (FIG. 7A). As a result, the contact portion 35e is formed on the interconnect layer 33 in the opening H2, and the contact portion 35d is formed on the via plugs 34 in the opening H3. At this time, since the length of the via plugs 34 exposed in the opening H3 is long, the contact portion 35d is formed in such a shape as a tip of a matchstick (FIG. 7B).

FIG. 7B shows the contact portion 35d in FIG. 7A by magnification. The interconnect layer 35 includes a barrier metal layer 35-1 and an interconnect material layer 35-2 in order. The interconnect material layer 35-2 is, for example, an Al (aluminum) layer. Forming the contact portion 35d in such a shape as a tip of a matchstick could cause connection failure, barrier failure, current concentration, EM failure, and the like in the contact portion 35d.

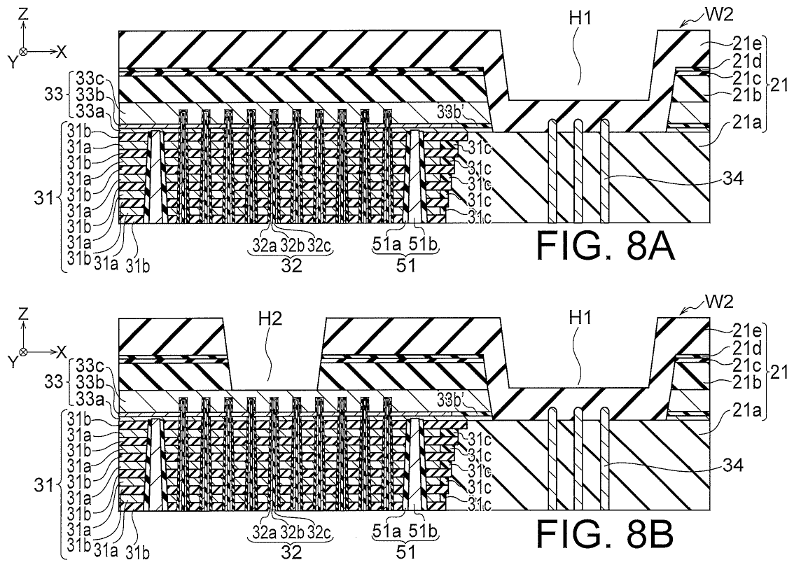

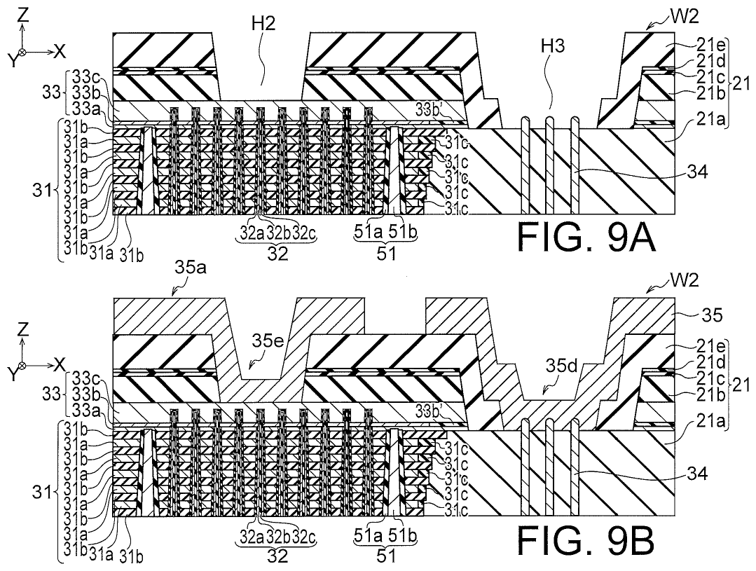

FIGS. 8A to 9B are cross-sectional views showing a method of manufacturing a semiconductor device of the second comparative example of the first embodiment.

A process shown in FIG. 8A is performed similarly to the process shown in FIG. 6A. Next, by lithography and RIE, the opening H2 is formed in the insulator 21e (FIG. 8B). Next, by lithography and RIE, the opening H3 is formed in the insulator 21e (FIG. 9A). The array wafer W2 of the present comparative example does not include the stacked film 31′ in the insulator 21a, either.

The RIE for the opening H3 is performed after the RIE for the opening H2, and thus, does not need to be performed so as to extend through the insulators 21b to 21e. Accordingly, the opening H3 shown in FIG. 9A is not deeply formed in the insulator 21a. As a result, the length of the via plugs 34 exposed in the opening H3 is reduced.

Next, the interconnect layer 35 is formed on the inter layer dielectric 21 (FIG. 9B). As a result, the contact portion 35e is formed on the interconnect layer 33 in the opening H2 and the contact portion 35d is formed on the via plugs 34 in the opening H3. The present comparative example makes it possible to restrict the contact portion 35d being formed in such a shape as a tip of a matchstick, since the length of the via plugs 34 exposed in the opening H3 is short. However, since the openings H2, H3 are sequentially formed, the number of processes for forming the openings H2, H3 increases.

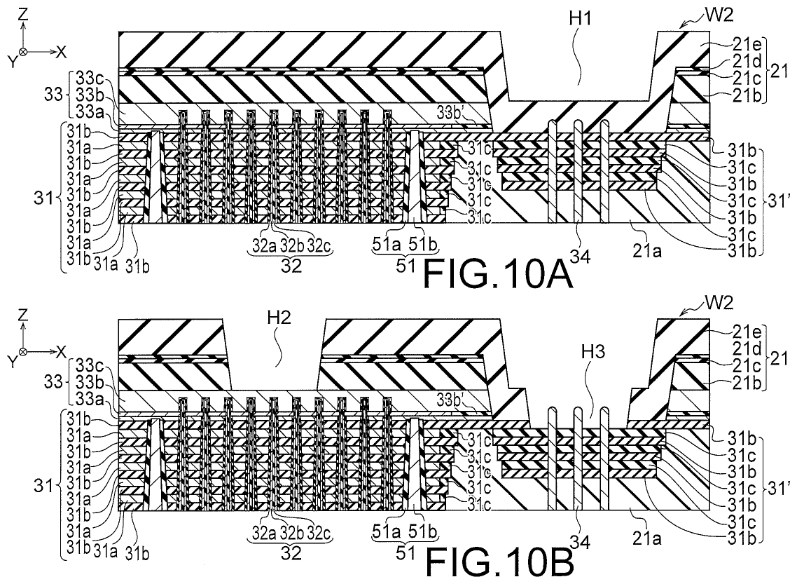

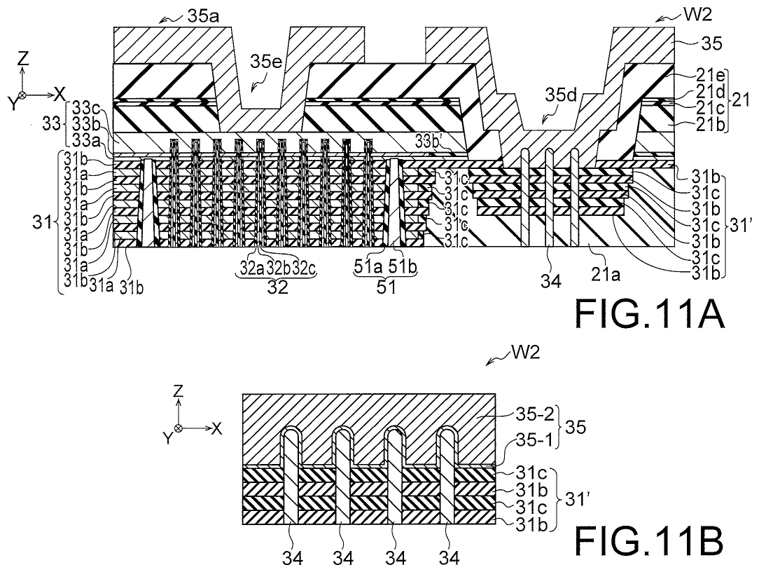

FIGS. 10A to 11B are cross-sectional views showing the method of manufacturing the semiconductor device of the first embodiment.

The process shown in FIG. 10A is performed similarly to the process shown in FIG. 6A. Next, by lithography and RIE, the openings H2, H3 are simultaneously formed in the insulator 21e (FIG. 10B).

The array wafer W2 of the present embodiment includes the stacked film 31′ in the insulator 21a as shown in FIG. 10B. In this case, the opening H3 extends through the insulator 21e and the uppermost insulator 31b and then reaches an upper face of the uppermost insulator 31c. Since the insulators 31c of the present embodiment are a SiN film, the uppermost insulator 31c functions as an etch stopper. Accordingly, the opening H3 shown in FIG. 10B is not deeply formed in the stacked film 31′. As a result, the length of the via plugs 34 exposed in the opening H3 is reduced.

Next, the interconnect layer 35 is formed on the inter layer dielectric 21 (FIG. 11A). As a result, the contact portion 35e is formed on the interconnect layer 33 in the opening H2 and the contact portion 35d is formed on the via plugs 34 in the opening H3. The present embodiment makes it possible to restrict the contact portion 35d being formed in such a shape as a tip of a matchstick, since the length of the via plugs 34 exposed in the opening H3 is short (FIG. 11B).

FIG. 11B shows the contact portion 35d shown in FIG. 11A by magnification. The interconnect layer 35 includes the barrier metal layer 35-1 and the interconnect material layer 35-2 in order. The present embodiment makes it possible to form the barrier metal layer 35-1 so as to restrict barrier failure, as shown in FIG. 11B. Further, the present embodiment makes it possible to form the openings H2, H3 with a fewer number of processes, by simultaneously forming the openings H2, H3.

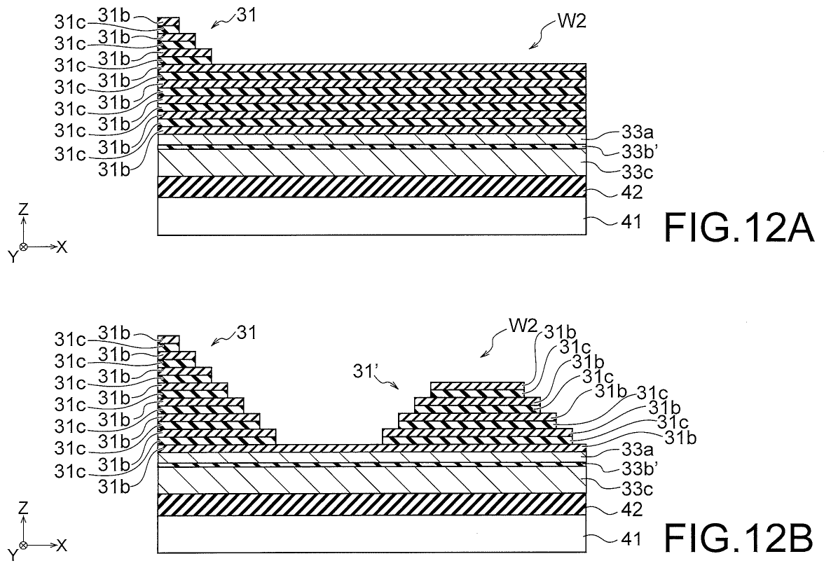

FIGS. 12A to 16B are cross-sectional views showing the method of manufacturing the semiconductor device of the first embodiment. FIGS. 12A to 16B show the details of the method shown in FIGS. 3 and 4.

In manufacturing the array wafer W2, the insulator 42, the layer 33c, the insulator 33b′, and the layer 33a are formed in order on the substrate 41 and the plurality of insulators 31b and the plurality of insulators 31c are alternately formed on the layer 33a (FIG. 12A).

Next, these insulators 31b, 31c are sequentially processed by etching (FIGS. 12A and 12B). As a result, the stacked films 31, 31′ are formed from these insulators 31b, 31c. The stacked film 31 is formed so as to include all the insulators 31b, 31c and the stacked film 31′ is formed so as to include only a part of the insulators 31b, 31c. FIG. 12A shows the process for processing the insulators 31b, 31c for the stacked film 31 and FIG. 12B shows the process for processing the insulators 31b, 31c for the stacked films 31, 31′. In the present embodiment, the stacked films 31, 31b′ are formed so as to include a stairway structure portion in a stairway shape.

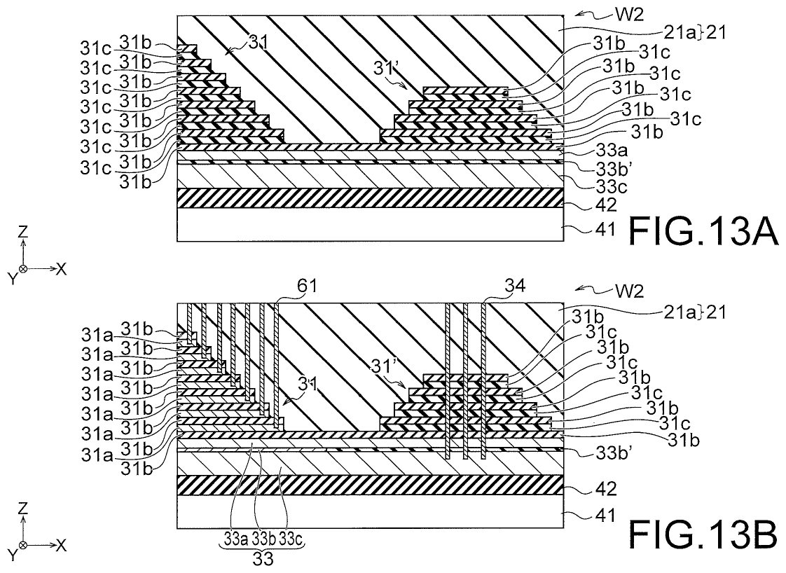

Next, the insulator 21a is formed on the layer 33a so as to cover the stacked films 31, 31′ and the surface of the insulator 21a is planarized by CMP (FIG. 13A).

Next, the insulators 31c are partially replaced with the electrode layers 31a, and the insulator 33b′ is partially replaced with the layer 33b (FIG. 13B). As a result, the insulators 31c in the stacked film 31 are at least partially replaced with the electrode layers 31a. Further, the interconnect layer 33 including the layers 33a to 33c is formed below the stacked film 31.

Next, a plurality of contact holes are formed in the insulator 21a and a plurality of contact plugs 61 are formed in these contact holes (FIG. 13B). These contact plugs 61 are formed on the stairway structure portion of the stacked film 31. Further, these contact plugs 61 are respectively formed on the plurality of electrode layers 31a and are electrically connected to these electrode layers 31a. These contact plugs 61 are an example of a second plug.

Next, a plurality of via holes are formed in the insulator 21a, the stacked film 31′, the layer 33a, the insulator 33b′, and the layer 33c, and the plurality of via plugs 34 are formed in these via holes (FIG. 13B). In the present embodiment, these via plugs 34 are formed so as not to reach the insulator 42.

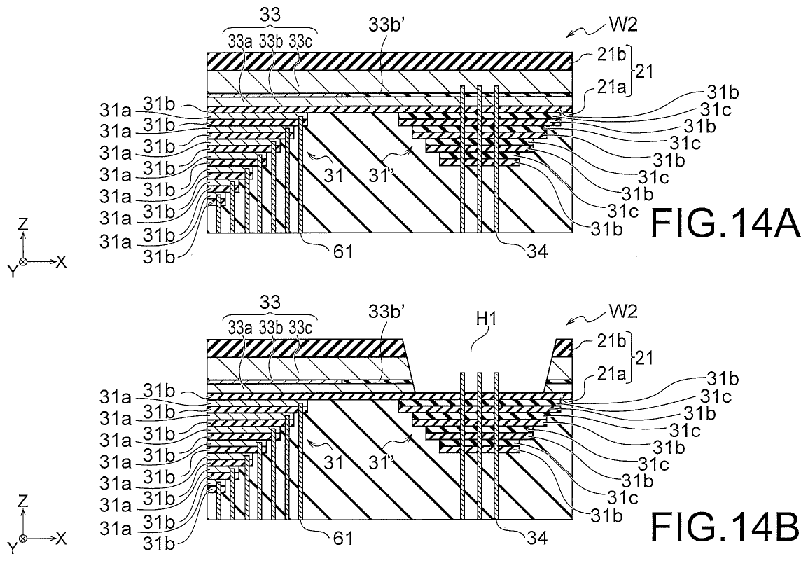

Thereafter, the array wafer W2 and the circuit wafer W1 are bonded together. FIG. 14A shows a process performed after bonding. FIG. 14A shows the contact plugs 61 disposed below the stairway structure portion of the stacked film 31 and the via plugs 34 disposed in the stacked film 31′.

First, the substrate 41 and the insulator 42 are removed and the insulators 21b to 21d are formed in order on the layer 33c (FIG. 14A). Illustration of the insulators 21c, 21d is omitted.

Next, by lithography and RIE, the opening H1 is formed in the insulator 21b, the layer 33c, the insulator 33b′, and the layer 33a (FIG. 14B). As a result, the stacked film 31′ and the plurality of via plugs 34 are exposed in the opening H1.

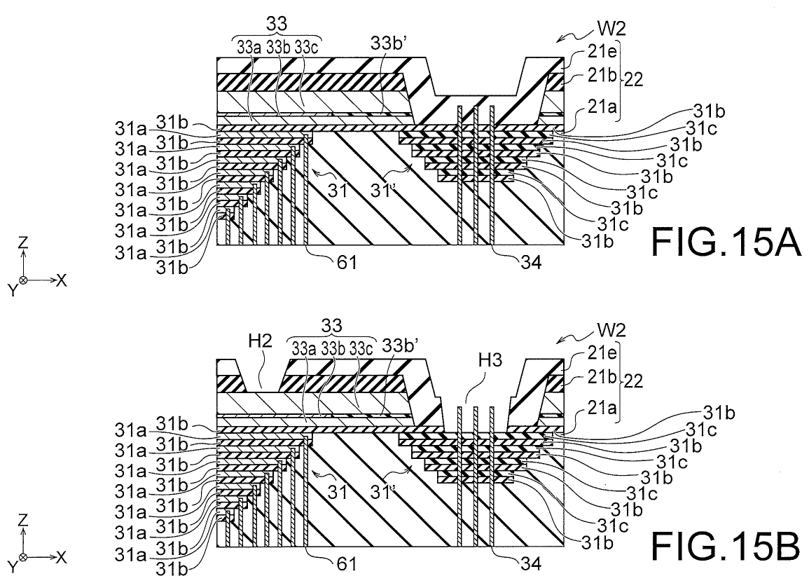

Next, the insulator 21e is formed on the insulator 21b (FIG. 15A). As a result, the insulator 21e is formed on the bottom face and the side face of the opening H1 so that the aforementioned via plugs 34 are covered with the insulator 21e.

Next, by lithography and RIE, the openings H2, H3 are simultaneously formed in the insulator 21e (FIG. 15B). The opening H2 is formed so as to extend through the insulators 21b, 21e and reach the source line (interconnect layer 33). The opening H3 is formed in the opening H1 so as to extend through the insulator 21e and the uppermost insulator 31b and reach the uppermost insulator 31c. As a result, the via plugs 34 are exposed in the opening H3. The uppermost insulator 31c functions as an etch stopper in RIE.

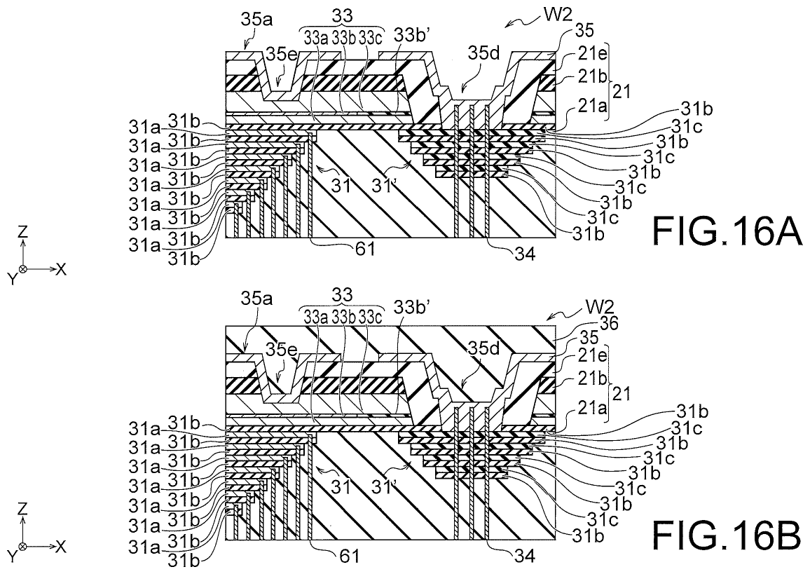

Next, the interconnect layer 35 is formed on the inter layer dielectric 21 (FIG. 16A). As a result, the contact portion 35e is formed on the interconnect layer 33 in the opening H2 and the contact portion 35d is formed on the via plugs 34 in the opening H3.

Next, the passivation insulator 36 is formed on the interconnect layer 35 (FIG. 16B). The passivation insulator 36 is formed by, for example, stacking plural types of insulators in order.

Thereafter, the circuit wafer W1 and the array wafer W2 are cut into a plurality of chips and the bonding wire 38 is attached to the interconnect layer 35 by means of the solder 37. In this manner, the semiconductor device shown in FIG. 1 is manufactured.

### (Modifications)

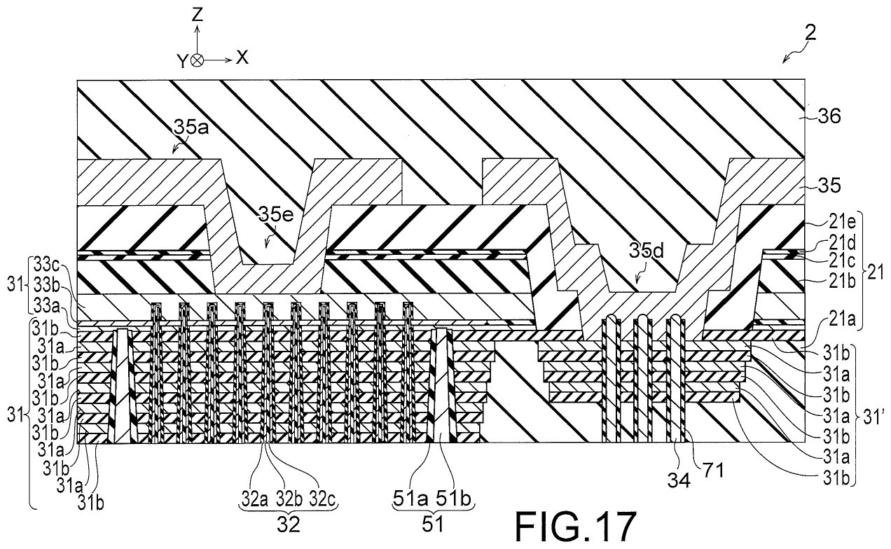

FIG. 17 is a cross-sectional view showing the structure of a semiconductor device of a first modification of the first embodiment.

The array chip 2 of the present modification has the same structure as that of the array chip 2 shown in FIG. 5. However, the stacked film 31′ of the present modification alternately includes the plurality of electrode layers 31a and the plurality of insulators 31b. The present modification makes it possible to use, as an etch stopper, the electrode layers 31a in place of the insulators 31c. The electrode layers 31a of the present modification are an example of the first film.

The via plugs 34 shown in FIG. 17 are formed in the stacked film 31′ via insulators 71 formed on side faces of the via plugs 34. This makes it possible to restrict the via plugs 34 being electrically connected to the electrode layers 31a. The insulators 71 are, for example, a SiO₂ film. The insulators 71 are an example of a third insulator. Further, the stacked film 31 shown in FIG. 17 does not include the insulators 31c as with the stacked film 31′.

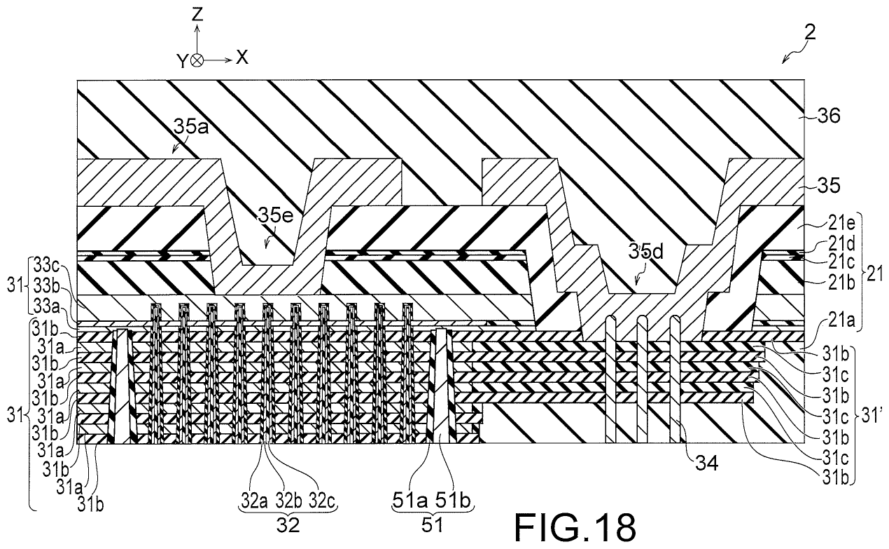

FIG. 18 is a cross-sectional view showing the structure of a semiconductor device of a second modification of the first embodiment.

The array chip 2 of the present modification has the same structure as that of the array chip 2 shown in FIG. 5. However, the insulators 31c in the stacked film 31′ of the present modification contact the corresponding electrode layers 31a in the stacked film 31, and the insulators 31b in the stacked film 31′ of the present modification contact the corresponding insulators 31b in the stacked film 31. The present modification makes it possible to use, as an etch stopper, the insulators 31c as with the case in FIG. 5.

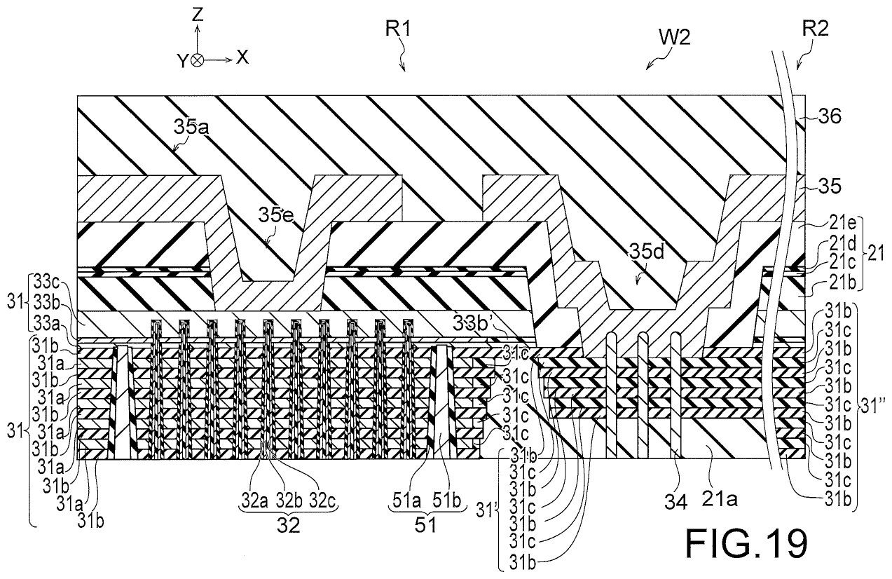

FIG. 19 is a cross-sectional view showing the structure of a semiconductor device of a third modification of the first embodiment before dicing.

The array wafer W2 of the present modification has the same structure as that of the array wafer W2 shown in FIG. 11A, except for the passivation insulator 36 already formed. However, the insulators 31c in the stacked film 31′ of the present modification contact the corresponding insulators 31c in a stacked film 31″, and the insulators 31b in the stacked film 31′ of the present modification contact the corresponding insulators 31b in the stacked film 31″.

FIG. 19 shows a chip region R1 and a scribe region R2 in the array wafer W2 (and the circuit wafer W1). The circuit wafer W1 and the array wafer W2 are cut into a plurality of chips in the scribe region R2. The stacked film 31″ is formed in the scribe region R2 and alternately includes the plurality of insulators 31b and the plurality of insulators 31c as with the stacked film 31′. The stacked films 31, 31′, 31″ are formed from the common insulators 31b, 31c and subsequently, the insulators 31c in the stacked film 31 are replaced with the electrode layers 31a. The present modification makes it possible to use, as an etch stopper, the insulators 31c as with the case in FIG. 5.

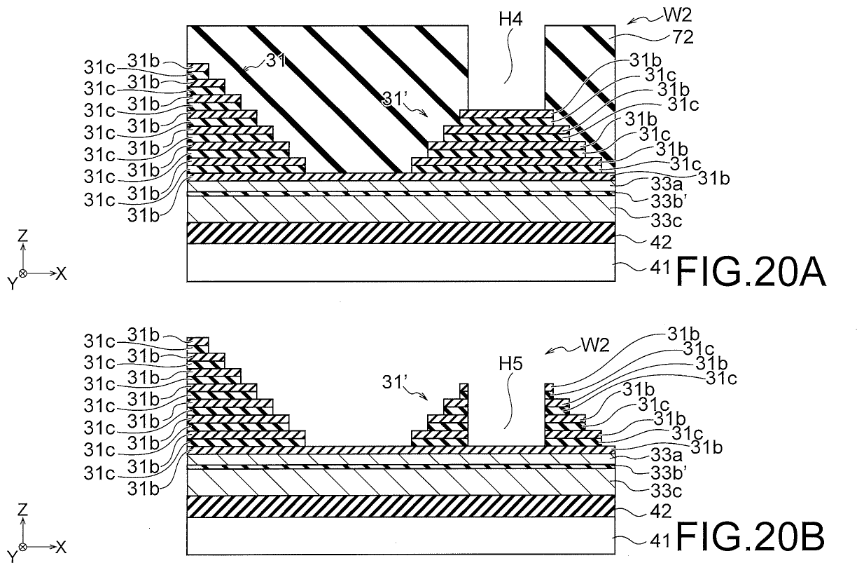

FIGS. 20A and 20B are cross-sectional views showing a method of manufacturing a semiconductor device of a fourth modification of the first embodiment.

In the present modification, the process in FIG. 20A and the process in FIG. 20B may be performed between the process in FIG. 12B and the process in FIG. 13A. In FIG. 20A, a resist film 72 is formed on the layer 33a so as to cover the stacked films 31, 31′ and an opening H4 is formed in the resist film 72. The opening H4 is formed on the stacked film 31′. In FIG. 20B, an opening H5 is formed in the stacked film 31′ below the opening H4 and subsequently, the resist film 72 is removed. As a result, the stacked film 31′ below the opening H5 includes one insulator 31c and one insulator 31b only. This insulator 31c is used as an etch stopper when the opening H3 shown in FIG. 15B is formed. The stacked film 31′ below the opening H5 may include two or more insulators 31c.

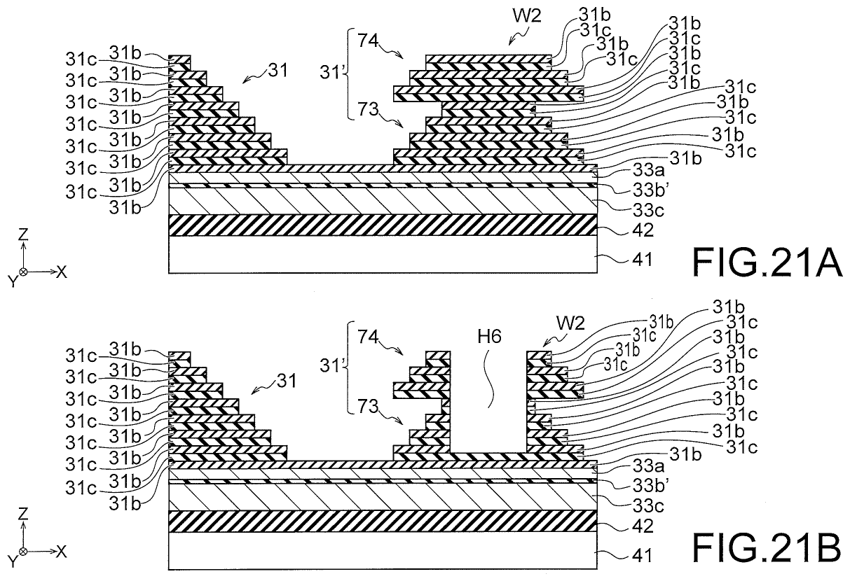

FIGS. 21A and 21B are cross-sectional views showing a method of manufacturing a semiconductor device of a fifth modification of the first embodiment.

In the present modification, the stacked film 31′ may be formed so as to include a lower stacked film 73 and an upper stacked film 74 (FIG. 21A). The lower stacked film 73 and the upper stacked film 74 include stairway structure portions that are different from each other. Further, the stacked film 31′ of the present modification may include an opening H6 as with the stacked film 31′ of the fourth modification. The stacked film 31′ below the opening H6 includes one insulator 31c and one insulator 31b only. This insulator 31c is used as an etch stopper when the opening H3 shown in FIG. 15B is formed. The stacked film 31′ below the opening H6 may include two or more insulators 31c.

As described above, the via plugs 34 below the contact portion 35d of the present embodiment are formed in the stacked film 31′. Accordingly, the present embodiment makes it possible to preferably form the interconnect layer 35 on the memory cell array (interconnect layer 33) and the via plugs 34. For example, it is possible to form the openings H2, H3 for the interconnect layer 35 with a fewer number of processes while restricting the contact portion 35d being formed in such a shape as a tip of a matchstick.

### Second Embodiment

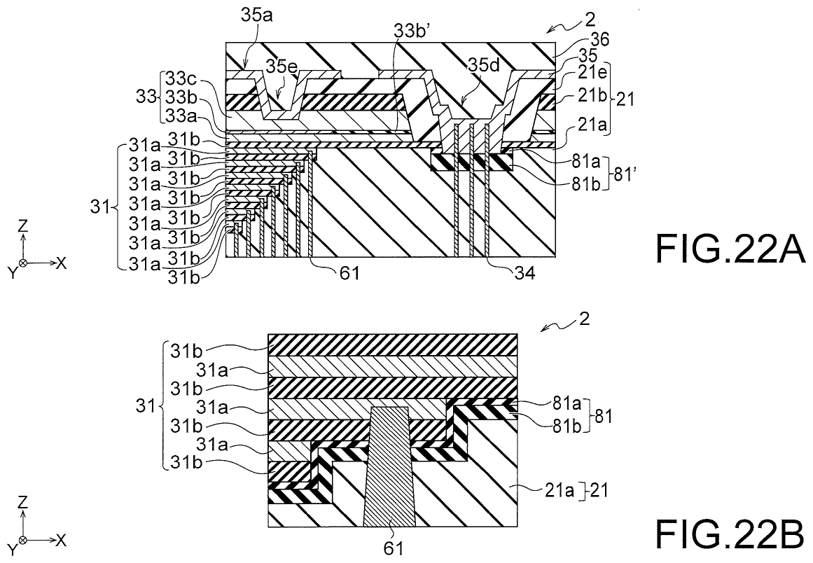

FIGS. 22A and 22B are cross-sectional views showing the structure of a semiconductor device of a second embodiment. FIG. 22A shows the structure of the array chip 2 of the present embodiment and FIG. 22B shows the enlarged view of FIG. 22A.

The semiconductor device of the present embodiment has the same structure as that of the semiconductor device shown in FIG. 5. However, the semiconductor device of the present embodiment includes cover insulators 81, 81′ in place of the stacked film 31′. The cover insulators 81, 81′ each include insulators 81a, 81b. The insulator 81a is, for example, a SiO₂ film. The insulator 81b is, for example, a SiN film. The cover insulator 81 is an example of a third stacked film and the cover insulator 81′ is an example of a fourth stacked film. The insulator 81a is an example of a fifth insulator and the insulator 81b is an example of a sixth insulator. In FIG. 22A, illustration of the cover insulator 81 is omitted.

The insulators 81a, 81b in the cover insulator 81 are formed in order on a lower face and a side face of the stairway structure portion of the stacked film 31. In FIG. 22B, one contact plug 61 is disposed below the stacked film 31, the one contact plug 61 extending through the cover insulator 81 and one insulator 31b and contacting the corresponding electrode layer 31a. Accordingly, this contact plug 61 is electrically connected to this electrode layer 31a. Similarly, in FIG. 22A, the plurality of contact plugs 61 are electrically connected to the plurality of electrode layers 31a, respectively. The stacked film 31 of the present embodiment may further include the plurality of insulators 31c as with the semiconductor device shown in FIG. 5.

The insulators 81a, 81b in the cover insulator 81′ are formed in order below the insulator 31b in the insulator 21a. Specifically, the insulator 81a is formed below the insulator 31b and the insulator 81b is formed below the insulator 81a and the contact portion 35d. In FIG. 22A, the plurality of via plugs 34 extend through the insulator 81b and is formed in and contacts the contact portion 35d. Accordingly, these via plugs 34 are electrically connected to the contact portion 35d.

The cover insulators 81, 81′ are formed such that before bonding described above, the insulators 81a, 81b are formed in order and the insulators 81a, 81b are processed into the cover insulators 81, 81′. In the present embodiment, when the insulators 81a, 81b are processed into the cover insulators 81, 81′, the insulators 81a, 81b are divided into the insulators 81a, 81b in the cover insulator 81 and the insulators 81a, 81b in the cover insulator 81′. As a result, the insulator 81a in the cover insulator 81 does not contact the insulator 81a in the cover insulator 81′, and the insulator 81b in the cover insulator 81 does not contact the insulator 81b in the cover insulator 81′. However, the insulator 81a in the cover insulator 81 may contact the insulator 81a in the cover insulator 81′ and the insulator 81b in the cover insulator 81 may contact the insulator 81b in the cover insulator 81′.

The insulator 81b in the cover insulator 81′ of the present embodiment is used as an etch stopper when the aforementioned opening H3 is formed, as with the uppermost insulator 31b in the stacked film 31′ of the first embodiment. Accordingly, the present embodiment makes it possible to enjoy the same advantage as that of the first embodiment.

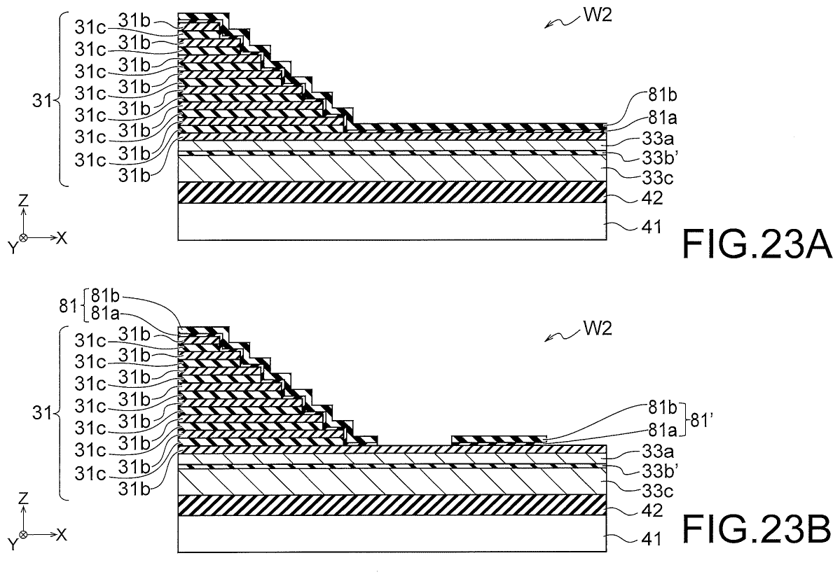

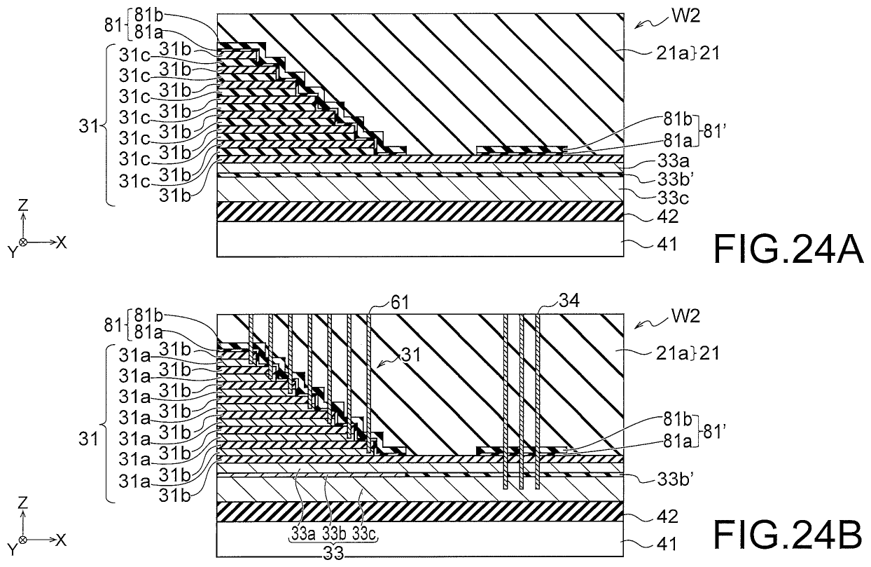

FIGS. 23A to 24B are cross-sectional views showing a method of manufacturing the semiconductor device of the second embodiment.

The semiconductor device of the present embodiment can be manufactured by the processes shown in FIGS. 12A to 16B similarly to the semiconductor device of the first embodiment. However, in the present embodiment, the processes shown in FIGS. 12A to 13B are replaced with the processes shown in FIGS. 23A to 24B.

First, similarly to the first embodiment, the stacked film 31 is formed from the insulators 31b, 31c (FIG. 23A). At this time, the stacked film 31′ is not formed from the insulators 31b, 31c. Next, the insulators 81a, 81b are formed in order on an upper face and a side face of the stacked film 31 (FIG. 23A). Next, by lithography and RIE, the insulators 81a, 81b are processed (FIG. 23B). As a result, the cover insulators 81, 81′ are formed from the insulators 81a, 81b.

Next, the insulator 21a is formed on the layer 33a so as to cover the stacked films 31, 31′ and the cover insulators 81, 81′, and the surface of the insulator 21a is planarized by CMP (FIG. 24A).

Next, the insulators 31c are replaced with the electrode layers 31a and the insulator 33b′ is partially replaced with the layer 33b (FIG. 24B). Next, a plurality of contact holes are formed in the insulator 21a and the cover insulator 81 and the plurality of contact plugs 61 are formed in these contact holes (FIG. 24B). These contact plugs 61 are formed on the corresponding electrode layers 31a, respectively. Next, a plurality of via holes are formed in the insulator 21a, the cover insulator 81′, the layer 33a, the insulator 33b′, and the layer 33c, and the plurality of via plugs 34 are formed in these via holes (FIG. 24B).

Thereafter, similarly to the first embodiment, the processes shown in FIGS. 14A to 16B are performed. However, in forming the opening H3, the insulator 81a in the cover insulator 81′ is used as an etch stopper in place of the uppermost insulator 31b in the stacked film 31′. In this manner, the semiconductor device of the present embodiment is manufactured.

As described above, the via plugs 34 below the contact portion 35d of the present embodiment are formed in the cover insulator 81′. Accordingly, the present embodiment makes it possible to preferably form the interconnect layer 35 on the memory cell array (interconnect layer 33) and the via plugs 34. For example, it is possible to form the openings H2, H3 for the interconnect layer 35 with a fewer number of processes while restricting the contact portion 35d being formed in such a shape as a tip of a matchstick.

### Third Embodiment

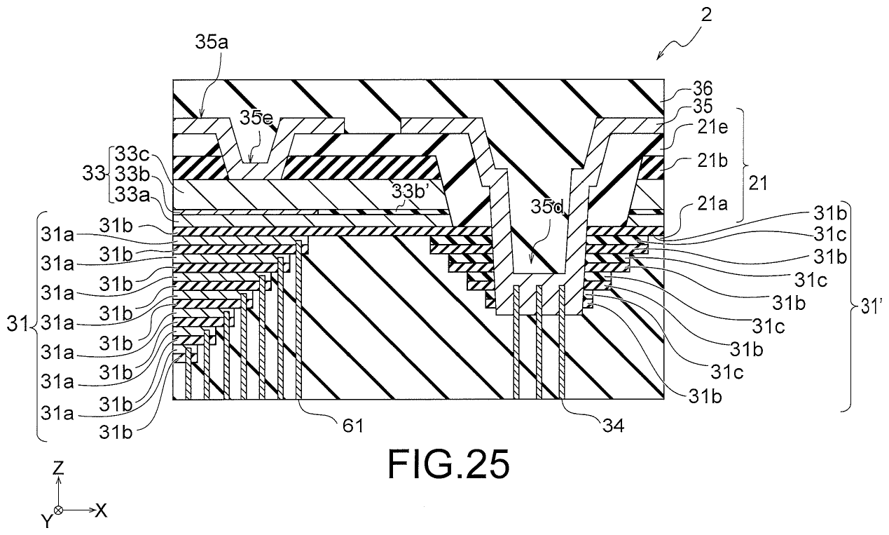

FIG. 25 is a cross-sectional view showing the structure of a semiconductor device of a third embodiment.

The semiconductor device of the present embodiment has the same structure as that of the semiconductor device shown in FIG. 5. However, the via plugs 34 shown in FIG. 25 have the upper ends at a lower position than the upper face of the stacked film 31′ (upper face of the uppermost insulator 31b) and at a higher position than the lower face of the stacked film 31′ (lower face of the lowermost insulator 31b). Further, the contact portion 35d shown in FIG. 25 has a lower face at a lower position than the lower face of the stacked film 31′ and extends through the stacked film 31′. Accordingly, the contact portion 35d is formed on the side faces of the insulators 31b and the insulators 31c in the stacked film 31′.

In the present embodiment, if the via plugs 34 have the upper ends at a higher position than the upper face of the stacked film 31′, the length of the via plugs 34 exposed in the opening H3 is increased. In this case, the contact portion 35d could be formed in such a shape as a tip of a matchstick. Meanwhile, as shown in FIG. 25, when the via plugs 34 have the upper ends at a lower position than the upper face of the stacked film 31′, the length of the via plugs 34 exposed in the opening H3 is reduced. This makes it possible to restrict the contact portion 35d being formed in such a shape as a tip of a matchstick.

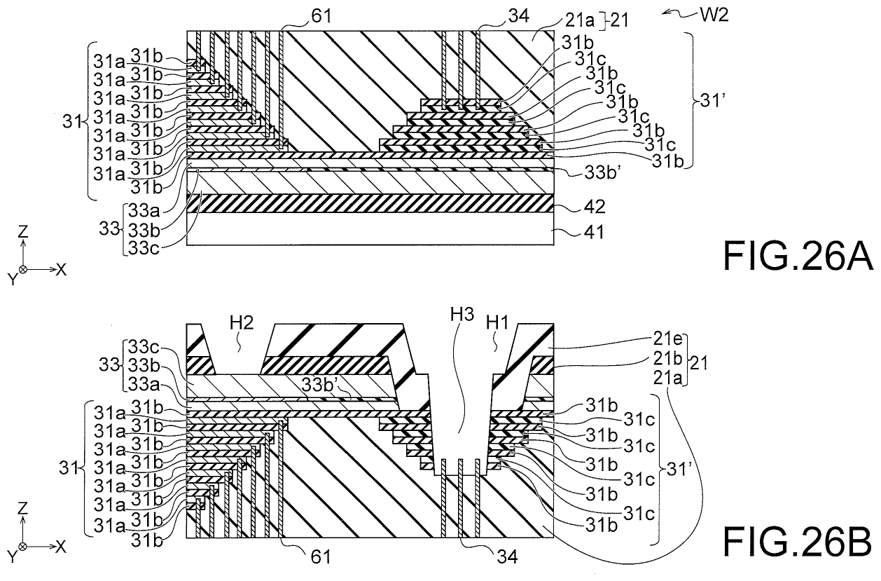

FIGS. 26A and 26B are cross-sectional views showing a method of manufacturing the semiconductor device of the third embodiment.

The semiconductor device of the present embodiment can be manufactured by the processes shown in FIGS. 12A to 16B similarly to the semiconductor device of the first embodiment. However, in the present embodiment, the process shown in FIG. 13B is replaced with the process shown in FIG. 26A, and the process shown in FIG. 15B is replaced with the process shown in FIG. 26B.

In FIG. 26A, a plurality of via holes are formed in the insulator 21a and the stacked film 31′, and the plurality of via plugs 34 are formed in these via holes. In the present embodiment, these via plugs 34 are formed so as not to reach the layer 33a. The via plugs 34 shown in FIG. 26A have the lower ends in the uppermost insulator 31c in the stacked film 31′.

In FIG. 26B, by lithography and RIE, the openings H2, H3 are simultaneously formed in the insulator 21e. At this time, the opening H3 is formed in the opening H1 so as to extend through the stacked film 31′ and reach the insulator 21a. Accordingly, if the length of the via plugs 34 exposed in the opening H3 is long, the contact portion 35d could be formed in such a shape as a tip of a matchstick. However, since the length of the via plugs 34 exposed in the opening H3 of the present embodiment is short, it is possible to restrict the contact portion 35d being formed in such a shape as a tip of a matchstick. In this manner, the semiconductor device of the present embodiment is manufactured.

As described above, the via plugs 34 below the contact portion 35d of the present embodiment are formed in the stacked film 31′ so as to have the upper ends at a lower position than the upper face of the stacked film 31′. Accordingly, the present embodiment makes it possible to preferably form the interconnect layer 35 on the memory cell array (interconnect layer 33) and the via plugs 34. For example, it is possible to form the openings H2, H3 for the interconnect layer 35 with a fewer number of processes while restricting the contact portion 35d being formed in such a shape as a tip of a matchstick.

### Fourth Embodiment

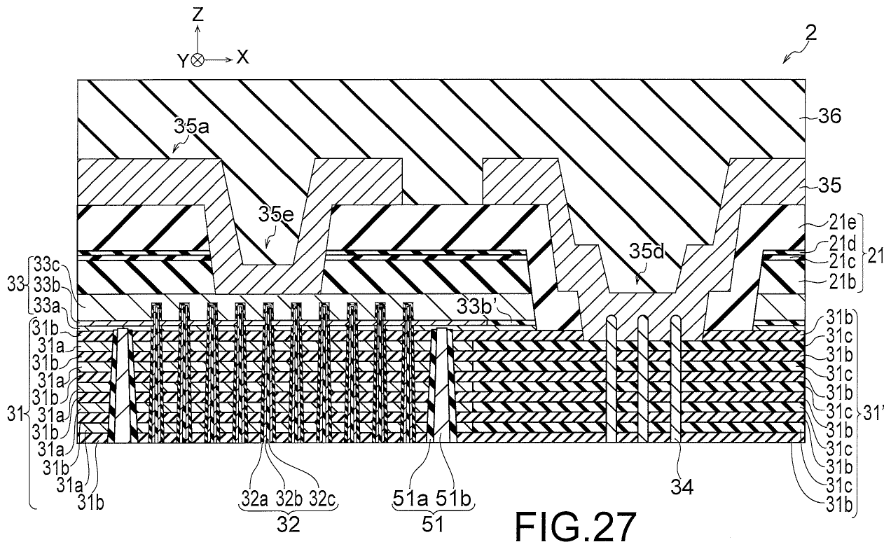

FIG. 27 is a cross-sectional view showing the structure of a semiconductor device of a fourth embodiment.

The semiconductor device of the present embodiment has the same structure as that of the semiconductor device shown in FIG. 5. However, the stacked films 31, 31′ of the present embodiment do not have a stairway structure. As a result, as described later, the contact plugs 61 of the present embodiment are formed in a manner different from the contact plugs 61 of the first embodiment. Further, the insulators 31c and the insulators 31b in the stacked film 31′ of the present embodiment contact the corresponding electrode layers 31a and the corresponding insulators 31b in the stacked film 31, respectively.

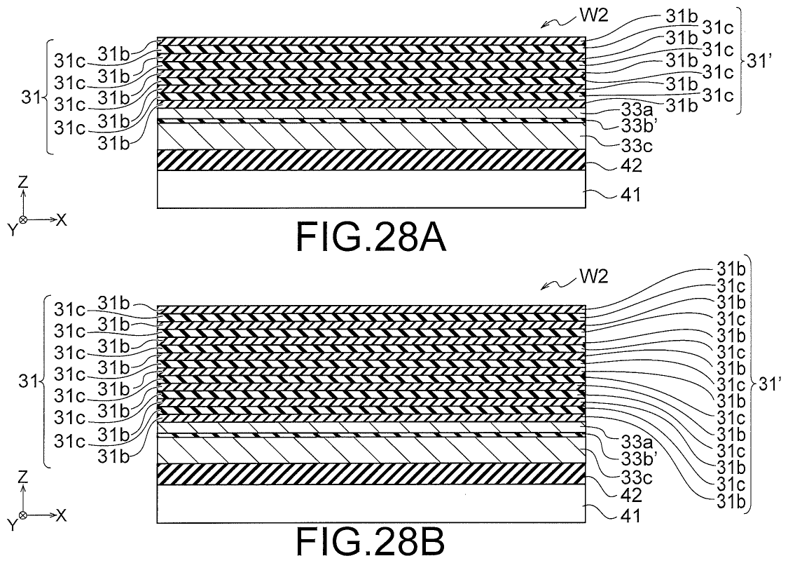

FIGS. 28A to 32B are cross-sectional views showing a method of manufacturing the semiconductor device of the fourth embodiment. In the illustrations of FIGS. 28A to 32B, the illustrations of the matters that are common to FIGS. 12A to 16B are omitted, as appropriate.

In manufacturing the array wafer W2, the insulator 42, the layer 33c, the insulator 33b′, and the layer 33a are formed in order on the substrate 41, and the plurality of insulators 31b and the plurality of insulators 31c are alternately formed on the layer 33a (FIGS. 28A and 28B). As a result, the stacked films 31, 31′ including the insulators 31b, 31c are formed on the layer 33a. FIG. 28A shows a state of the insulators 31b, 31c shown in FIG. 28B partially formed.

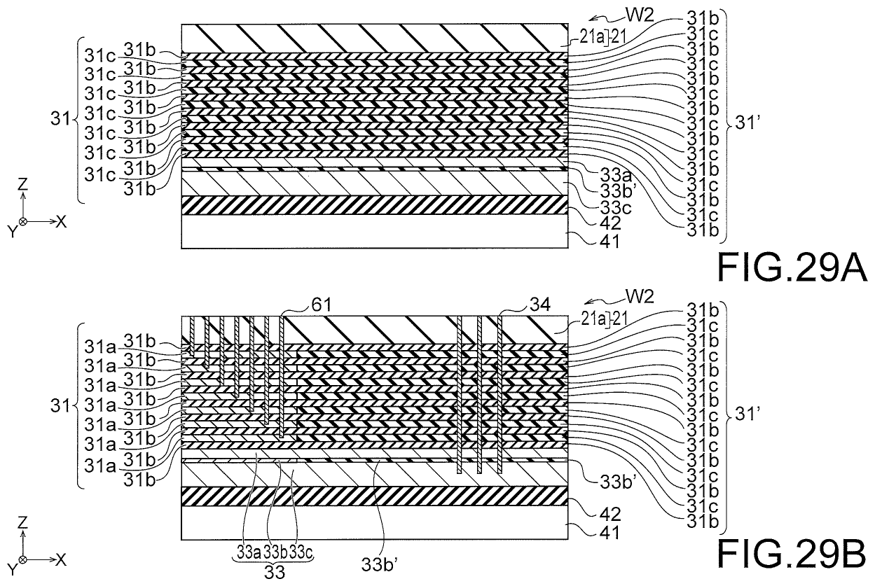

Next, the insulator 21a is formed on the layer 33a so as to cover the stacked films 31, 31′ and the surface of the insulator 21a is planarized by CMP (FIG. 29A).

Next, the insulators 31c are partially replaced with the electrode layers 31a, and the insulator 33b′ is partially replaced with the layer 33b (FIG. 29B). As a result, the insulators 31c in the stacked film 31 are replaced with the electrode layers 31a. Further, the interconnect layer 33 including the layers 33a to 33c is formed below the stacked film 31.

Next, a plurality of contact holes are formed in the insulator 21a and the plurality of contact plugs 61 are formed in these contact holes (FIG. 29B). As with the contact plugs 61 of the first embodiment, the contact plugs 61 of the present embodiment are formed on and electrically connected to the corresponding electrode layers 31a. However, except for the contact plug 61 corresponding to the uppermost electrode layer 31a, the contact plugs 61 of the present embodiment are formed so as to extend through one or more electrode layers 31a above the corresponding electrode layers 31a.

Next, a plurality of via holes are formed in the insulator 21a, the stacked film 31′, the layer 33a, the insulator 33b′, and the layer 33c, and the plurality of via plugs 34 are formed in these via holes (FIG. 29B). In the present embodiment, these via plugs 34 are formed so as not to reach the insulator 42.

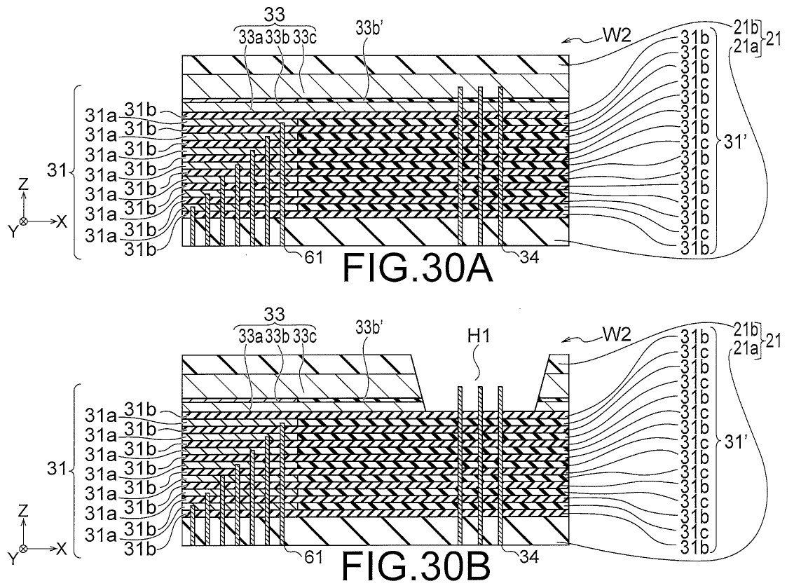

Thereafter, the array wafer W2 and the circuit wafer W1 are bonded together. FIG. 30A shows a process performed after bonding. FIG. 30A shows the contact plugs 61 disposed in the stacked film 31 and the via plugs 34 disposed in the stacked film 31′.

First, the substrate 41 and the insulator 42 are removed, and the insulators 21b to 21d are formed in order on the layer 33c (FIG. 30A). Illustration of the insulators 21c, 21d is omitted.

Next, by lithography and RIE, the opening H1 is formed in the insulator 21b, the layer 33c, the insulator 33b′, and the layer 33a (FIG. 30B). As a result, the stacked film 31′ and the plurality of via plugs 34 are exposed in the opening H1.

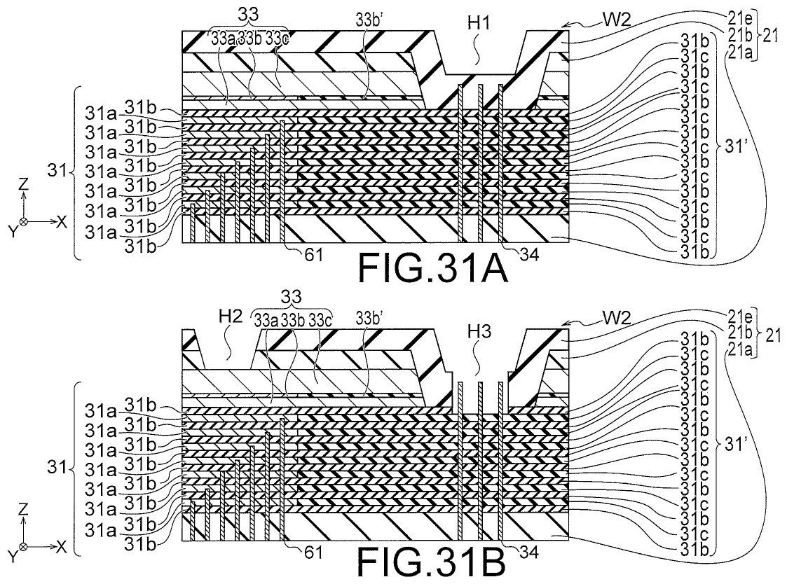

Next, the insulator 21e is formed on the insulator 21b (FIG. 31A). As a result, the insulator 21e is formed on the bottom face and the side face of the opening H1 so that the aforementioned via plugs 34 are covered with the insulator 21e.

Next, by lithography and RIE, the openings H2, H3 are simultaneously formed in the insulator 21e (FIG. 31B). The opening H2 is formed so as to extend through the insulators 21b, 21e and reach the source line (interconnect layer 33). The opening H3 is formed in the opening H1 so as to extend through the insulator 21e and the uppermost insulator 31b and reach the uppermost insulator 31c. As a result, the via plugs 34 are exposed in the opening H3. The uppermost insulator 31c functions as an etch stopper in RIE.

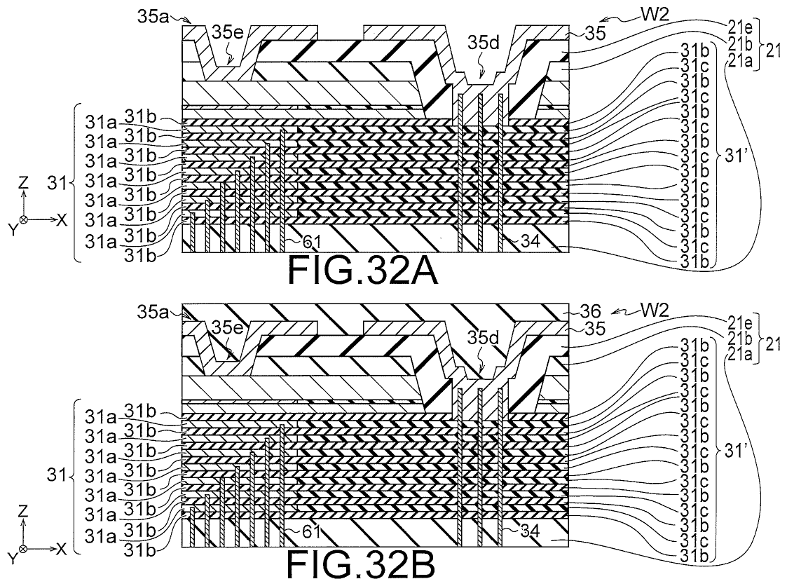

Next, the interconnect layer 35 is formed on the inter layer dielectric 21 (FIG. 32A). As a result, the contact portion 35e is formed on the interconnect layer 33 in the opening H2 and the contact portion 35d is formed on the via plugs 34 in the opening H3.

Next, the passivation insulator 36 is formed on the interconnect layer 35 (FIG. 32B). The passivation insulator 36 is formed by, for example, stacking plural types of insulators in order.

Thereafter, the circuit wafer W1 and the array wafer W2 are cut into a plurality of chips and the bonding wire 38 is attached to the interconnect layer 35 by means of the solder 37. In this manner, the semiconductor device of the present embodiment is manufactured.

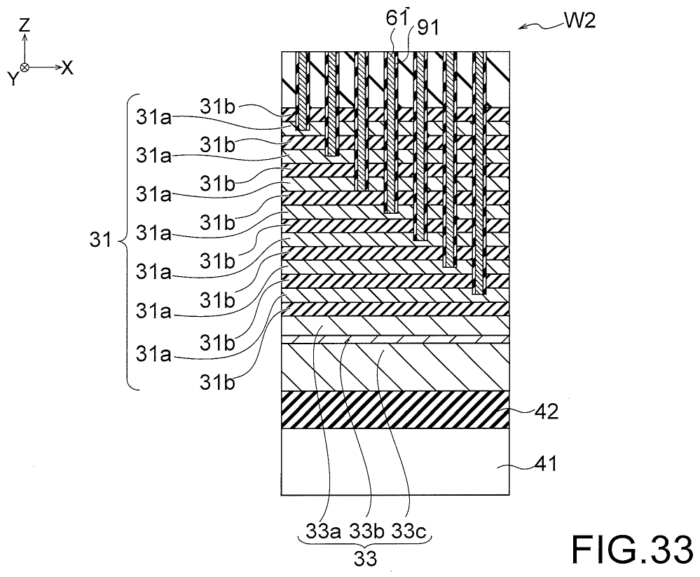

FIG. 33 is a cross-sectional view showing the structure of the semiconductor device of the fourth embodiment before bonding. FIG. 33 shows an enlarged view of FIG. 30A.

Except for the contact plug 61 corresponding to the uppermost electrode layer 31a, the contact plugs 61 of the present embodiment are formed so as to extend through one or more electrode layers 31a above the corresponding electrode layers 31a. Therefore, the contact plugs 61 of the present embodiment need to be electrically insulated from one or more electrode layers 31a through which the contact plugs 61 extend.

Therefore, the contact plugs 61 of the present embodiment are formed in the corresponding contact holes via insulators 91 (FIG. 33). The insulators 91 are, for example, a SiO₂ film. In FIG. 33, the contact plugs 61 are provided in the stacked film 31 via the insulators 91 provided on side faces of the contact plugs 61. Meanwhile, bottom faces of the contact plugs 61 are not covered with the insulators 91 and contact the corresponding electrode layers 31a. The insulators 91 are an example of a fourth insulator.

As described above, the via plugs 34 below the contact portion 35d of the present embodiment are formed in the stacked film 31′. Accordingly, the present embodiment makes it possible to preferably form the interconnect layer 35 on the memory cell array (interconnect layer 33) and the via plugs 34. For example, it is possible to form the openings H2, H3 for the interconnect layer 35 with a fewer number of processes while restricting the contact portion 35d being formed in such a shape as a tip of a matchstick.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a substrate;
a first stacked film provided above the substrate, includes a plurality of electrode layers and a plurality of first insulators that are alternately stacked in a first direction, and included in a memory cell array;
a second stacked film provided above the substrate, includes one or more first insulators of the plurality of first insulators, and one or more first films that are stacked alternately with the one or more first insulators in the first direction;
a first plug provided in the second stacked film; and
a first interconnect layer provided on the memory cell array and the first plug, and electrically connected to the memory cell array and the first plug.

2. The device of claim 1, wherein
the memory cell array includes:
the first stacked film including the plurality of electrode layers and the plurality of first insulators;
a columnar portion provided in the first stacked film, extending in the first direction, and including a semiconductor layer; and
a second interconnect layer provided on the first stacked film, and electrically connected to the columnar portion, and
the first interconnect layer is provided on the second interconnect layer and the first plug, and is electrically connected to the second interconnect layer and the first plug.

3. The device of claim 1, wherein the one or more first films are one or more second insulators formed of an insulating material that is different from an insulating material of the one or more first insulators.

4. The device of claim 3, wherein the one or more first insulators include silicon and oxygen, and the one or more second insulators include silicon and nitrogen.

5. The device of claim 1, wherein the one or more first films are one or more electrode layers of the plurality of electrode layers.

6. The device of claim 5, wherein the first plug is provided in the second stacked film via a third insulator that is provided on a side face of the first plug.

7. The device of claim 1, wherein the plurality of electrode layers and the one or more first films do not include an electrode layer and a first film that are in contact with each other.

8. The device of claim 1, wherein the plurality of electrode layers and the one or more first films include an electrode layer and a first film that are in contact with each other.

9. The device of claim 1, further comprising a plurality of second plugs respectively electrically connected to the plurality of electrode layers.

10. The device of claim 9, wherein the plurality of second plugs are provided below a stairway structure portion of the first stacked film.

11. The device of claim 9, wherein the plurality of second plugs are provided in the first stacked film via a plurality of fourth insulators that are respectively provided on side faces of the plurality of second plugs.

12. A semiconductor device comprising:
a substrate;
a first stacked film provided above the substrate, including a plurality of electrode layers and a plurality of first insulators that are alternately stacked in a first direction, and included in a memory cell array;
a third stacked film provided on a lower face and a side face of a stairway structure portion of the first stacked film, and including a fifth insulator and a sixth insulator that is provided below the fifth insulator;
a fourth stacked film provided above the substrate, including the fifth insulator and the sixth insulator that is provided below the fifth insulator;
a first plug provided in the fourth stacked film; and
a first interconnect layer provided on the memory cell array and the first plug, and electrically connected to the memory cell array and the first plug.

13. The device of claim 12, wherein
the memory cell array includes:
the first stacked film including the plurality of electrode layers and the plurality of first insulators;
a columnar portion provided in the first stacked film, extending in the first direction, and including a semiconductor layer; and
a second interconnect layer provided on the first stacked film, and electrically connected to the columnar portion, and
the first interconnect layer is provided on the second interconnect layer and the first plug, and is electrically connected to the second interconnect layer and the first plug.

14. The device of claim 12, wherein the fifth insulator includes silicon and oxygen, and the sixth insulator includes silicon and nitrogen.

15. The device of claim 12, further comprising a plurality of second plugs respectively electrically connected to the plurality of electrode layers.

16. The device of claim 15, wherein the plurality of second plugs are provided below the stairway structure portion of the first stacked film, and are provided in the third stacked film.

17. A semiconductor device comprising:
a substrate;
a first stacked film provided above the substrate, including a plurality of electrode layers and a plurality of first insulators that are alternately stacked in a first direction, and included in a memory cell array;
a second stacked film provided above the substrate, including one or more first insulators of the plurality of first insulators, and one or more first films that are stacked alternately with the one or more first insulators in the first direction;
a first plug provided in the second stacked film, and having an upper end at a lower position than an upper face of the second stacked film; and
a first interconnect layer provided on the memory cell array and the first plug, having a lower face at a lower position than a lower face of the second stacked film, and electrically connected to the memory cell array and the first plug.

18. The device of claim 17, wherein
the memory cell array includes:
the first stacked film including the plurality of electrode layers and the plurality of first insulators;
a columnar portion provided in the first stacked film, extending in the first direction, and including a semiconductor layer; and
a second interconnect layer provided on the first stacked film, and electrically connected to the columnar portion, and
the first interconnect layer is provided on the second interconnect layer and the first plug, and is electrically connected to the second interconnect layer and the first plug.

19. The device of claim 17, wherein the first plug has the upper end at a higher position than the lower face of the second stacked film.

20. The device of claim 17, wherein the first interconnect layer is provided on side faces of the one or more first films of the second stacked film.
